(19) United States
(12) Patent Application Publication
(10) Pub. No.: US 2020/0185384 A1
(43) Pub. Date: Jun. 11, 2020

(54) HORIZONTAL GATE-ALL-AROUND (GAA) FIELD EFFECT TRANSISTOR (FET) FOR COMPLEMENTARY METAL OXIDE SEMICONDUCTOR (CMOS) INTEGRATION

(71) Applicant: QUALCOMM Incorporated, San Diego, CA (US)

(72) Inventors: Xia LI, San Diego, CA (US); Bin YANG, San Diego, CA (US); Gengming TAO, San Diego, CA (US)

(21) Appl. No.: 16/216,883

(22) Filed: Dec. 11, 2018

(51) Int. Cl. H01L 27/092; H01L 29/78; H01L 29/08; H01L 29/66; H01L 29/06; H01L 29/10; H01L 21/033; H01L 21/8238; H01L 29/417

(52) U.S. Cl. CPC H01L 27/0924; H01L 27/0925; H01L 29/785; H01L 29/0847; H01L 29/66545; H01L 29/0673; H01L 2029/7858; H01L 21/0337; H01L 21/823821; H01L 21/823878; H01L 21/823892; H01L 29/41725; H01L 29/1033

(57) ABSTRACT

A horizontal gate-all-around (GAA) field effect transistor (FET) is described. The horizontal GAA FET includes a substrate as well as a shallow trench isolation (STI) region on the substrate. The horizontal GAA FET includes a first nano-sheet structure on the substrate and extending through the STI region. The first nano-sheet structure includes a first drain/source region stacked on a first source/drain region. The first nano-sheet structure also includes a first channel region between the first drain/source region and the first source/drain region. The horizontal GAA FET also includes a first gate on the STI region and horizontally surrounding the first channel region on four sides.

### BACKGROUND

### Field

Aspects of the present disclosure relate to semiconductor devices and, more particularly, to a horizontal, gate-all-around (GAA) field effect transistor (FET) for complementary metal oxide semiconductor (CMOS) integration.

### Background

As integrated circuit (IC) technology advances, device geometries are reduced. Reducing the geometry and “pitch” (spacing) between devices may cause devices to interfere with each other and adversely affect operation.

Fin-based devices are three-dimensional structures on the surface of a semiconductor substrate. A fin-based transistor, which may be a fin-based metal oxide semiconductor field effect transistor (MOSFET), may be referred to as a FinFET. A nanowire field effect transistor (FET) is also a three-dimensional structure on the surface of a semiconductor substrate. A nanowire FET includes doped portions of the nanowire that contact a channel region and serve as the source and drain regions of the device. A nanowire FET is also an example of a MOSFET device.

As integrated circuit (IC) technology advances, device geometries are reduced. Reducing the geometry and “pitch” (spacing) between devices complicates fabrication of fin-based devices. Furthermore, the continued scaling reduces a fin width. The reduced fin width combined with the high aspect ratio of fin-based devices substantially degrades the mechanical integrity of these fin-based devices.

### SUMMARY

A horizontal gate-all-around (GAA) field effect transistor (FET) is described. The horizontal GAA FET includes a substrate as well as a shallow trench isolation (STI) region on the substrate. The horizontal GAA FET includes a first nano-sheet structure on the substrate and extending through the STI region. The first nano-sheet structure includes a first drain/source region stacked on a first source/drain region. The first nano-sheet structure also includes a first channel region between the first drain/source region and the first source/drain region. The horizontal GAA FET also includes a first gate on the STI region and horizontally surrounding the first channel region on four sides.

A method for fabricating a horizontal gate-all-around (GAA) field effect transistor (FET) is described. The method includes patterning multilayer epitaxial semiconductor layers grown on a substrate according to a nano-slab hardmask pattern to form a nano-slab structure of the horizontal GAA FET. The horizontal GAA FET including at least a channel region and a source region. The method also includes replacing a dummy gate on the channel region of the nano-slab structure with a gate on a shallow trench isolation (STI) region. The gate horizontally surrounds the channel region on four sides. The method further includes epitaxially growing a drain region on the channel region of the nano-slab structure.

A horizontal gate-all-around (GAA) field effect transistor (FET) is described. The horizontal GAA FET includes a substrate as well as a shallow trench isolation (STI) region on the substrate. The horizontal GAA FET includes a first nano-sheet structure on the substrate and extending through the STI region. The first nano-sheet structure includes a first drain/source region stacked on a first source/drain region. The first nano-sheet structure also includes a first channel region between the first drain/source region and the first source/drain region. The horizontal GAA FET also includes means for horizontally surrounding the first channel region on four sides. The means for horizontally surrounding is on the STI region.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer.

FIG. 2 illustrates a cross-sectional view of a die.

FIG. 3 illustrates a cross-sectional view of a metal oxide semiconductor field effect transistor (MOSFET) device.

FIG. 4 illustrates a fin field effect transistor (FinFET).

FIG. 5 illustrates horizontal, gate-all-around (GAA) field effect transistors (FETs) of an integrated circuit, according to aspects of the present disclosure.

FIG. 6 is a block diagram illustrating a top view of horizontal, gate-all-around (GAA) field effect transistors (FETs) of the integrated circuit of FIG. 5 in P-type metal oxide semiconductor (PMOS) configurations and N-type metal oxide semiconductor (NMOS) configurations, according to aspects of the present disclosure.

FIG. 7 is a block diagram illustrating a top view of horizontal, gate-all-around (GAA) field effect transistors (FETs) of the integrated circuit of FIG. 5 in a P-type metal oxide semiconductor (PMOS) configuration and an N-type metal oxide semiconductor (NMOS) configuration, according to further aspects of the present disclosure.

FIG. 8 is a block diagram further illustrating a top view of horizontal, gate-all-around (GAA) field effect transistors (FETs) of the integrated circuit of FIG. 5 in a P-type metal oxide semiconductor (PMOS) configuration and an N-type metal oxide semiconductor (NMOS) configuration, according to further aspects of the present disclosure.

FIG. 9 is a block diagram further illustrating a top view of horizontal, gate-all-around (GAA) field effect transistors (FETs) of the integrated circuit of FIG. 5 in a P-type metal oxide semiconductor (PMOS) configuration and an N-type metal oxide semiconductor (NMOS) configuration, according to further aspects of the present disclosure.

FIGS. 10A and 10B illustrate cross-sectional views of the horizontal, gate-all-around (GAA) field effect transistors (FETs) shown in FIG. 6, according to aspects of the present disclosure.

FIGS. 11A and 11B illustrate cross-sectional views of the horizontal, gate-all-around (GAA) field effect transistors (FETs) shown in FIG. 6, according to aspects of the present disclosure.

FIGS. 12A-12K are block diagrams illustrating a process for fabricating the integrated circuit of FIG. 6, including horizontal, gate-all-around (GAA) field effect transistors (FETs), according to aspects of the present disclosure.

FIG. 13 is a process flow diagram illustrating a method of fabricating a horizontal gate-all-around (GAA) field effect transistor (FET), according to aspects of the present disclosure.

FIG. 14 is a block diagram showing an exemplary wireless communication system in which an aspect of the disclosure may be advantageously employed.

FIG. 15 is a block diagram illustrating a design workstation used for circuit, layout, and logic design of a transistor structure according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Fin-based devices represent a significant advance in integrated circuit (IC) technology over planar-based devices. Fin-based devices are three-dimensional structures on the surface of a semiconductor substrate. A FinFET transistor is a fin-based metal oxide semiconductor field effect transistor (MOSFET). A nanowire field effect transistor (FET) also represents a significant advance in IC technology. A gate-all-around (GAA) nanowire-based device is also a three-dimensional structure on the surface of a semiconductor substrate. A GAA nanowire-based device includes doped portions of the nanowire that contact a channel region and serve as the source and drain regions of the device. A GAA nanowire-based device is also an example of a MOSFET device.

As integrated circuit (IC) technology advances, device geometries are reduced. Reducing the geometry and “pitch” (spacing) between devices complicates fabrication of fin-based devices. For example, continued scaling leads to production of high aspect ratio (AR) fins for vertical gate, fin-based devices, in which a gate is vertically deposited over three sides of the fin-based device. Furthermore, the continued scaling reduces a fin width. The reduced fin width combined with the high aspect ratio of vertical gate, fin-based devices substantially degrades the mechanical integrity of these vertical gate, fin-based devices. For example, the fins of these vertical gate, fin-based devices may bend due to their degraded mechanical integrity. In addition, under sufficient stress, dummy gates built with vertical gate, fin-based devices may collapse.

Various aspects of the disclosure provide a horizontal, gate-all-around (GAA) field effect transistor (FET) compatible with complementary metal oxide semiconductor (CMOS) integration. The process flow for fabricating the horizontal, GAA FET may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably unless such interchanging would tax credulity.

According to aspects of the present disclosure, a horizontal, gate-all-around (GAA) field effect transistor (FET) compatible with complementary metal oxide semiconductor (CMOS) integration is described. The horizontal GAA FET includes a shallow trench isolation (STI) region on a substrate. The horizontal GAA FET also includes a nano-sheet structure (e.g., a nano-slab or vertical nano-slab) on the substrate and extending through the STI region. The nano-sheet structure may include a drain/source region stacked on a source/drain region. In one configuration, the nano-sheet structure may also include a channel region between the drain/source region and the source/drain region. In this configuration, the horizontal GAA FET includes a gate on the STI region and horizontally surrounding the channel region on four sides of the channel region of the nano-sheet structure. In aspects of the present disclosure, a gate length of the horizontal GAA FET is defined by an epitaxial thickness of the channel region of the nanostructure.

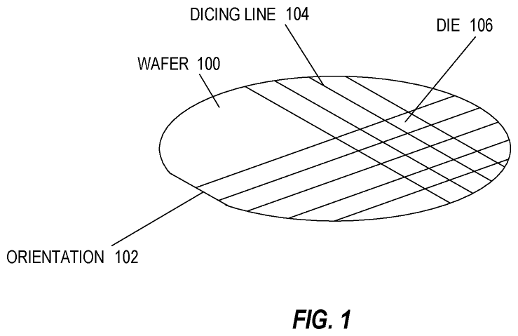

FIG. 1 illustrates a perspective view of a semiconductor wafer, which may be used for fabricating a horizontal GAA FET, according to aspects of the present disclosure. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a single material (e.g., silicon) or a compound material, such as gallium arsenide (GaAs) or gallium nitride (GaN), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and [symbol] , which are the Miller indices for a plane (hk [symbol] ) in the crystal. Each index denotes a plane orthogonal to a direction (h, k, [symbol] ) on the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to [symbol] . For some crystals, negative numbers are used (written as a bar over the index number) and for some crystals, such as gallium nitride, more than three numbers may be employed to adequately describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

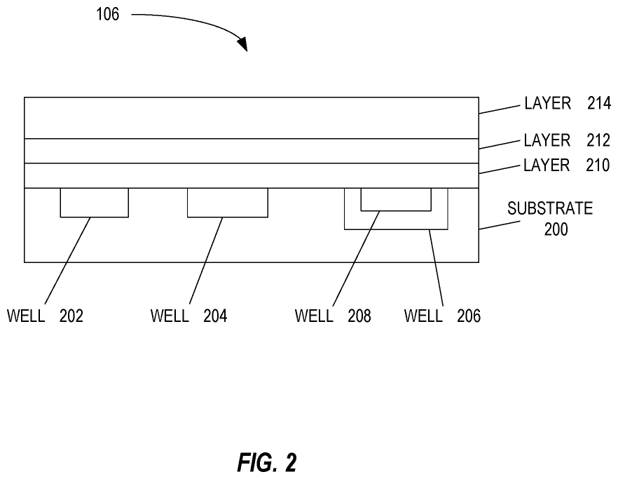

FIG. 2 illustrates a cross-sectional view of a die 106, which may be used for fabricating a horizontal GAA FET, according to aspects of the present disclosure. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within a substrate 200 (e.g., a semiconductor substrate), there may be wells 202 and 204 of a field effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT). The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

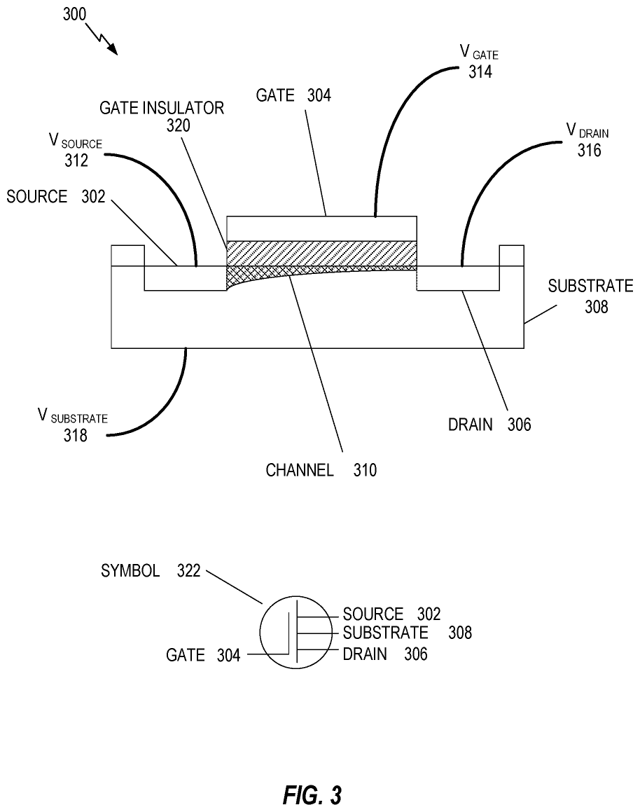

FIG. 3 illustrates a cross-sectional view of a metal oxide semiconductor field effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For p-type MOSFETs (using holes as charge carriers in the channel 310), an arrow is applied to the substrate 308 terminal in the symbol 322 pointing toward the gate 304 terminal.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304, as described below.

To interconnect to the MOSFET device 300, or to interconnect to other devices in the die 106 (e.g., semiconductor), interconnect traces or layers are used. These interconnect traces may be in one or more layers (e.g., 210-214), or may be in other layers of the die 106.

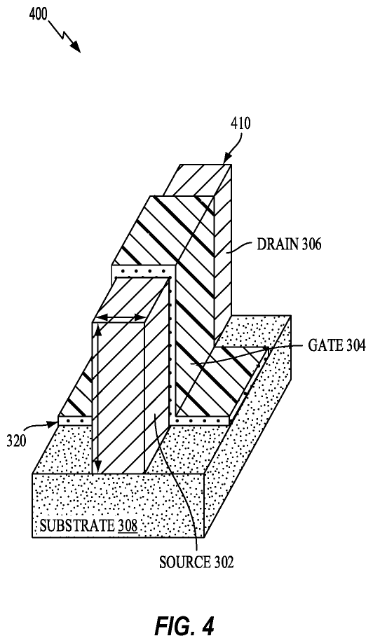

FIG. 4 illustrates a vertical fin-structured FET (FinFET 400) that operates in a similar fashion to the MOSFET device 300 described with respect to FIG. 3. A fin 410 in a FinFET 400, however, is grown or otherwise coupled to the substrate 308. The substrate 308 may be a semiconductor substrate or other like supporting layer, for example, comprised of an oxide layer, a nitride layer, a metal oxide layer, or a silicon layer. The fin 410 includes the source 302 and the drain 306. A gate 304 is disposed on the fin 410 and on the substrate 308 through a gate insulator 320. In a FinFET structure, the physical size of the FinFET 400 may be smaller than the MOSFET device 300 structure shown in FIG. 3. This reduction in physical size allows for more devices per unit area on the die 106.

The FinFET 400 may be fabricated through processes including a front-end-of-line (FEOL), a middle-of-line (MOL) and a back-end-of-line (BEOL). A middle-of-line process includes gate and terminal contact formation. A middle-of-line layer trench contacts the source and drain regions of the FinFET 400 and is referred to as CA contacts.

Fin-based devices, such as the FinFET 400, represent a significant advance in integrated circuit (IC) technology over planar-based devices. Fin-based devices are three-dimensional structures on the surface of a semiconductor substrate. A FinFET transistor is a fin-based metal oxide semiconductor field effect transistor (MOSFET). A nanowire field effect transistor (FET) also represents a significant advance in IC technology. A gate-all-around (GAA) nanowire-based device is also a three-dimensional structure on the surface of a semiconductor substrate. A GAA nanowire-based device includes doped portions of the nanowire that contact a channel region and serve as the source and drain regions of the device. A GAA nanowire-based device is also an example of a MOSFET device.

As integrated circuit (IC) technology advances, device geometries are reduced. Reducing the geometry and “pitch” (spacing) between devices complicates fabrication of fin-based devices. For example, continued scaling leads to production of high aspect ratio (AR) fins for vertical gate, fin-based devices, such as the FinFET 400. In vertical gate, fin-based devices, the gate 304 is vertically deposited on three sides of the fin 410, including opposing sides and a top of the fin 410, as shown in FIG. 4. In addition, the source 302 and the drain 306 are formed from opposing lateral portions of the fin 410. Furthermore, the continued scaling reduces a fin width. The reduced fin width and the high aspect ratio of vertical gate, fin-based devices substantially degrades the mechanical integrity of these vertical gate, fin-based devices, such as the FinFET 400.

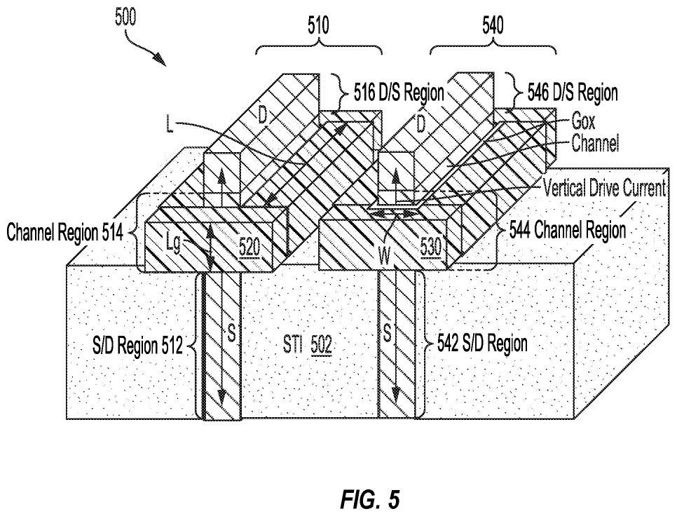

According to aspects of the present disclosure, a horizontal, gate-all-around (GAA) field effect transistor (FinFET) compatible with complementary metal oxide semiconductor (CMOS) integration is described, for example, with reference to FIG. 5.

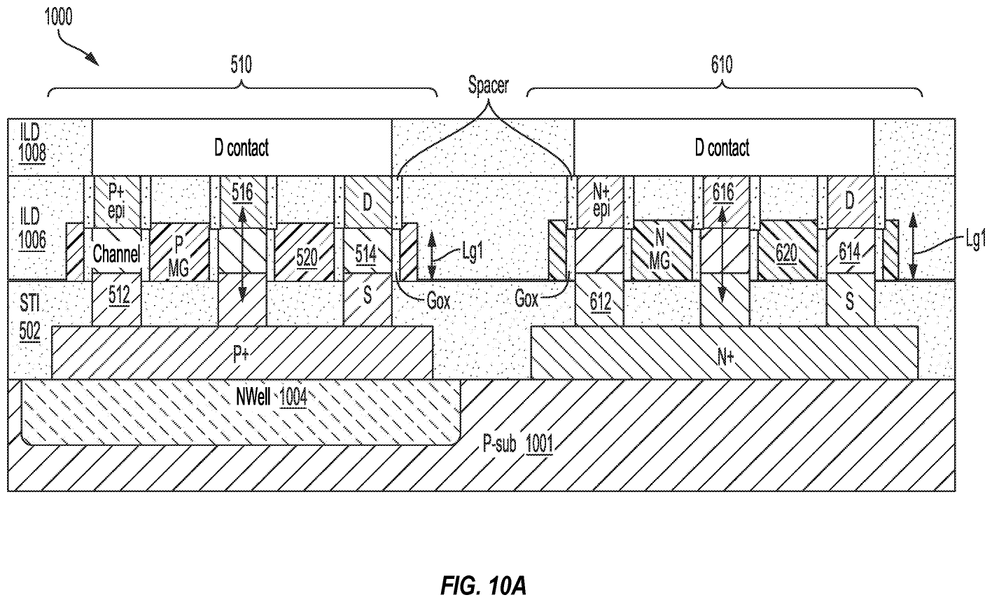

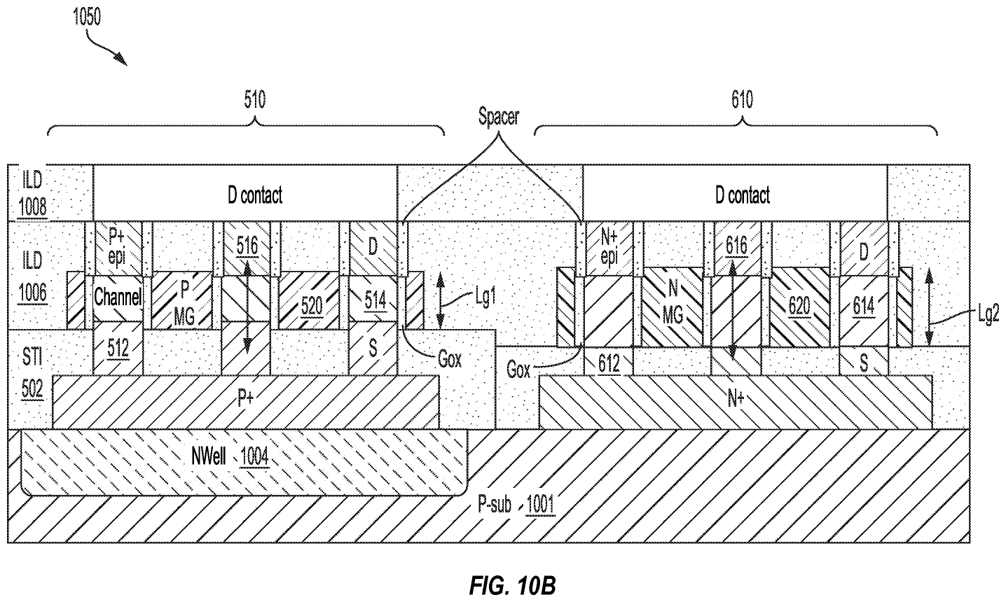

FIG. 5 illustrates horizontal, gate-all-around (GAA) field effect transistors (FETs) of an integrated circuit, according to aspects of the present disclosure. In this configuration, the integrated circuit 500 includes a first GAA FET 510 (e.g., a first horizontal GAA FET) and a second GAA FET 540 (e.g., a second horizontal GAA FET), each supported by a shallow trench isolation (STI) region 502. The first GAA FET 510 is composed of a first nano-sheet structure supported by a substrate (see FIGS. 10A-B, 11A-B, and 12A-12K) and extending through the STI region 502. The first nano-sheet structure may include a drain/source (D/S) region 516 (e.g., a first drain/source region) stacked on a source/drain (S/D) region 512 (e.g., a first source/drain region). In one configuration, the first nano-sheet structure includes a channel region 514 (e.g., a first channel region) between the S/D region 512 and the D/S region 516. In this example, the S/D region 512 is shown as a source region (S) extending through the STI region 502. In addition, the D/S region 516 is shown as a drain region (D) on the channel region 514.

In aspects of the present disclosure, the first GAA FET 510 also includes a gate 520 (e.g., a first gate) on the STI region 502 and horizontally surrounding the channel region 514 on four sides of the first nano-sheet structure. In this aspect of the present disclosure, a gate length (Lg) of the gate 520 of the first GAA FET 510 is defined by an epitaxial thickness of a channel region 514 of the first nano-sheet structure. The gate length Lg may be in the range of five (5) to fifteen (15) nanometers, to enable transistor fabrication at process nodes below seven (7) nanometers (nm). This configuration results in the first GAA FET having a reduced aspect ratio (AR), for example, in the range of four (4) to (5), which maintains mechanical integrity. In addition, the D/S region 516 and the S/D region 512 are formed from opposing vertical ends of the first nano-sheet structure, which may be referred to as a first nano-slab. This configuration provides a vertical drive current between the vertical source and drain regions.

The integrated circuit 500 also includes the second GAA FET 540. The second GAA FET 540 is composed of a second nano-sheet structure supported by a substrate (see FIGS. 10A-B, 11A-B, and 12A-12K) and extending through the STI region 502. The second nano-sheet structure may include a D/S region 546 (e.g., a second drain/source region) stacked on an S/D region 542 (e.g., a second source/drain region). The second nano-sheet structure may also include a channel region 544 (e.g., a second channel region) formed between the D/S region 546 and the S/D region 542. In this configuration, the channel region 544 is between the S/D region 542 and the D/S region 546. In this configuration, the second GAA FET 540 also includes a gate 530 (e.g., a second gate) on the STI region 502 and horizontally surrounding the channel region 514 on four sides of the second nano-sheet structure. In aspects of the present disclosure, a gate length Lg of the gate 530 of the second GAA FET 540 is defined by an epitaxial thickness of the channel region 514 of the second nano-sheet structure.

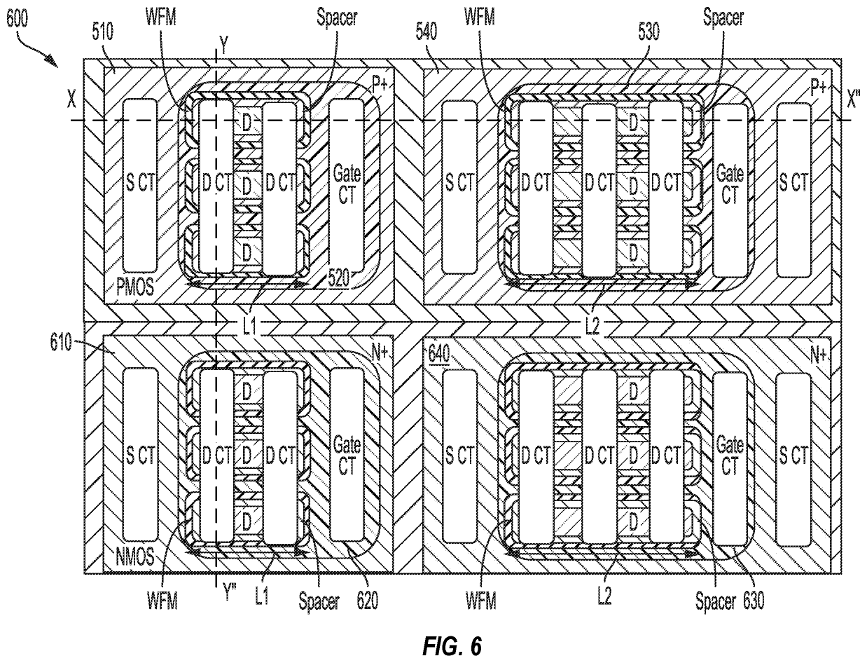

Although two horizontal GAA FETs (e.g., 510 and 540) are shown, it is understood that this is exemplary, and more or fewer horizontal GAA FETs are possible. As described, the first nano-sheet structure and the second nano-sheet structure may refer to a vertical fin slab structure. According to aspects of the present disclosure, the vertical nano-slab structure includes a channel region (e.g., 514 and/or 544) horizontally surrounded by a gate (e.g., 520 and/or 530) on four sides of the vertical nano-slab structure. The configuration simplifies fabricating the gate length Lg, which is defined by an epitaxial thickness of the channel region (e.g., 514 and/or 544). As described in further detail below, the gate length Lg and a nano-slab length (L) between the first GAA FET 510 and the second GAA FET 540 may vary, for example, as shown in FIGS. 6-9, to provide different channel widths.

FIGS. 6-9 are block diagrams illustrating top views of various configurations of the GAA FETs (e.g., 510 and 540) shown in FIG. 5, according to aspects of the present disclosure. The various configurations of the GAA FETs shown in FIGS. 6-9 illustrate gate length variations as well as channel width variations between the GAA FETs (e.g., 510 and 540) shown in FIG. 5. An x-axis (X-X″) and a y-axis (Y-Y″) are also shown.

FIG. 6 is a block diagram 600 illustrating a top view of the first GAA FET 510 and the second GAA FET 540 in a P-type metal oxide semiconductor (PMOS) configuration, and a third GAA FET 610 and a fourth GAA FET 640 in an N-type metal oxide semiconductor (NMOS) configuration of an integrated circuit, according to aspects of the present disclosure. In one configuration, the first GAA FET 510 includes drain nano-slabs (D) horizontally surrounded by the gate 520. The drain nano-slabs D include a spacer and channel nano-slab regions (not shown) surrounded by a work function material(s) (WFM) to form the gate 520. A gate contact (Gate CT), drain contacts (DCT), and a source contact (SCT) are also shown.

FIG. 6 also illustrates the top view of the second GAA FET 540 in a configuration similar to the first GAA FET 510. In the configuration shown in FIG. 6, a nano-slab length (L1) of the drain nano-slabs D (e.g., a first nano-slab length) of the first GAA FET 510 is less than a nano-slab length (L2) of the drain nano-slabs D (e.g., a second nano-slab length) of the second GAA FET 540 to provide different channel widths. FIG. 6 also shows the third GAA FET 610 and the fourth GAA FET 640 in the NMOS configuration. Representatively, the third GAA FET 610 is configured similar to the first GAA FET 510, and the fourth GAA FET 640 is configured similar to the second GAA FET 540. In particular, a nano-slab length (L1) of the drain nano-slabs D of the third GAA FET 610 is also less than a nano-slab length (L2) of the drain nano-slabs D of the fourth GAA FET 640 in the NMOS configuration, which enables configurations of different channel widths.

According to aspects of the present disclosure, the work function material (WFM) may be deposited over a dielectric layer on a channel nano-slab (e.g., a high-K gate dielectric). The high-K gate dielectric layer may be deposited over a gate oxide (Gox) surrounding the channel nano-slab. A gate metal fill material may include tungsten (W) deposited on the WFM to form a high-K metal gate as the gate 520 and/or the gate 530 of the first GAA FET 510 and the second GAA FET 540, as well as a gate 620 and/or the gate 630 of the third GAA FET 610 and the fourth GAA FET 640.

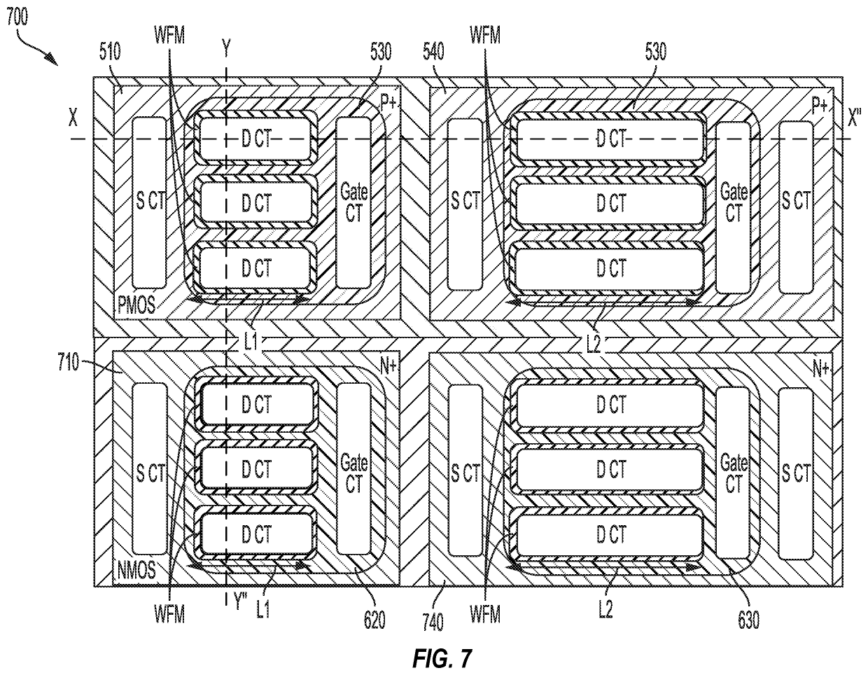

FIG. 7 is a block diagram 700 illustrating a top view of the first GAA FET 510 and the second GAA FET 540 of FIG. 5 in a PMOS configuration, and a third GAA FET 710 and a fourth GAA FET 740 in an NMOS configuration, according to aspects of the present disclosure. This configuration of the first GAA FET 510 and the second GAA FET 540 as well as the third GAA FET 710 and the fourth GAA FET 740 is similar to the configuration shown in FIG. 6. In this configuration, however, the drain contacts DCT to the drain nano-slabs D are orthogonal to the drain contacts DCT shown in FIG. 6. In this configuration, the nano-slab length L1 of the drain nano-slabs D of the third GAA FET 710 is also less than a nano-slab length L2 of the drain nano-slabs D of the fourth GAA FET 740 in the NMOS configuration. The source contacts (SCT) and the gate contacts (Gate CT) are similar to the configuration shown in FIG. 6.

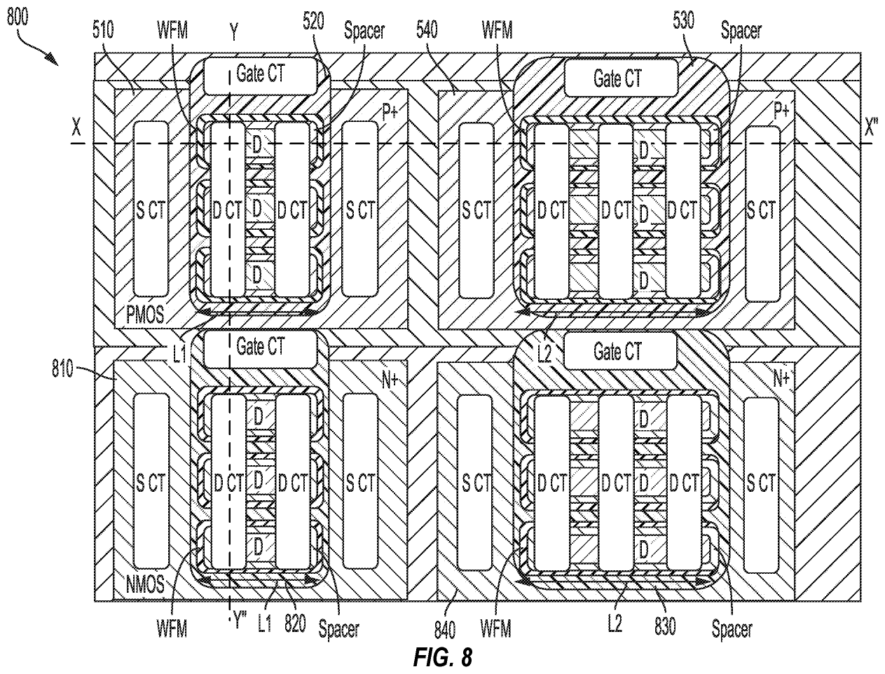

FIG. 8 is a block diagram 800 illustrating a top view of the first GAA FET 510 and the second GAA FET 540 of FIG. 5 in a PMOS configuration, and a third GAA FET 810 and a fourth GAA FET 840 in an NMOS configuration, according to aspects of the present disclosure. This configuration of the first GAA FET 510 and the second GAA FET 540 as well as the third GAA FET 810 and the fourth GAA FET 840 is similar to the configuration shown in FIG. 6. In this configuration, however, the gate contacts (Gate CT) to the gates (e.g., 520, 530, 820, and 830) are adjacent to the gate contacts (Gate CT) shown in FIG. 6. In this configuration, the nano-slab length L1 of the drain nano-slabs D of the third GAA FET 810 is also less than a nano-slab length L2 of the drain nano-slabs D of the fourth GAA FET 840 in the NMOS configuration. The source contacts (SCT) and the drain contacts (DCT) are similar to the configuration shown in FIG. 6.

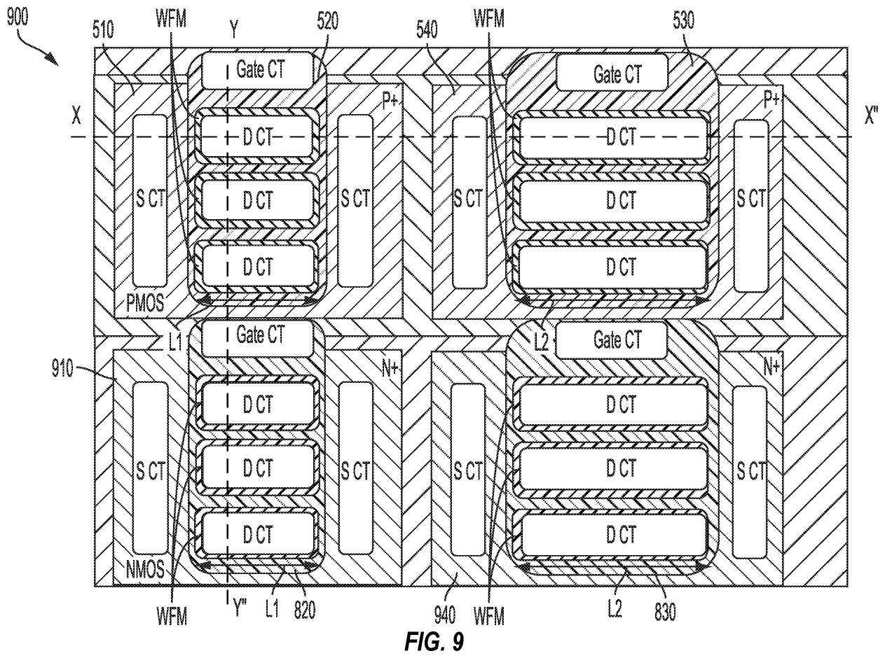

FIG. 9 is a block diagram 900 illustrating a top view of the first GAA FET 510 and the second GAA FET 540 of FIG. 5 in a PMOS configuration, and a third GAA FET 910 and a fourth GAA FET 940 in an NMOS configuration, according to aspects of the present disclosure. This configuration of the first GAA FET 510 and the second GAA FET 540 as well as the third GAA FET 910 and the fourth GAA FET 940 is similar to the configuration shown in FIG. 8. In this configuration, however, the drain contacts DCT to the drain nano-slabs D are orthogonal to the drain contacts DCT shown in FIG. 8. In addition, the nano-slab length L1 of the drain nano-slabs D of the third GAA FET 910 is also less than a nano-slab length L2 of the drain nano-slabs D of the fourth GAA FET 940 in the NMOS configuration. The source contacts (SCT) and the gate contacts (Gate CT) are similar to the configuration shown in FIG. 8.

FIGS. 10A and 10B illustrate cross-sectional views of the horizontal GAA FETs shown in FIG. 6, according to aspects of the present disclosure. FIG. 10A shows a cross-sectional view along the Y-Y″ axis of the first GAA FET 510 and the third GAA FET 610 of the integrated circuit shown in FIG. 6. In this configuration, an integrated circuit 1000 includes a substrate 1001 (e.g., a P-type semiconductor substrate (P-sub)), including an N-type well (N-well 1004) supporting the first GAA FET 510 in a PMOS configuration. The cross-sectional view illustrates nano-sheet structures including the drain region 516 stacked on the channel region 514, which is stacked on the source region 512. The gate 520 is also shown surrounding a gate oxide (Gox) on the channel region 514. Spacers are shown on sidewalls of the drain region 516 in the cross-sectional view. The drain contact (D contact) to drain region 516 is also provided. A gate length (Lg1) of the first GAA FET 510 (e.g., a first gate length) is also shown. The integrated circuit 1000 also includes an STI region 502, a first inter-dielectric (ILD) 1006 on the STI region 502, and a second ILD 1008 on the first ILD 1006. These layers may be formed using an oxide film, which may be composed of silicon nitride (SiN).

FIG. 10A also shows the third GAA FET 610 of the integrated circuit shown in FIG. 6. This configuration of the integrated circuit 1000 shows nano-sheet structures including a drain region 616 stacked on a channel region 614, which is stacked on a source region 612. A gate 620 is shown surrounding a gate oxide Gox on the channel region 614. Spacers are shown on sidewalls of the drain region 616 in the cross-sectional view. The drain contact (D contact) to drain region 616 is also provided. In this configuration, the gate length (Lg1) of the third GAA FET 610 (e.g., a second gate length) matches the gate length Lg1 of the first GAA FET 510.

FIG. 10B shows a cross-sectional view along the Y-Y″ axis of the first GAA FET 510 and the third GAA FET 610 of the integrated circuit shown in FIG. 6. In this configuration, an integrated circuit 1050 is shown in a similar configuration to the integrated circuit 1000 shown in FIG. 10A. In the configuration shown in FIG. 10B, however, the gate length (Lg2) of the third GAA FET 610 is greater than the gate length Lg1 of the first GAA FET 510. Variation of the gate length of the integrated circuit 1050 provides improved flexibility for design of the first GAA FET 510 and the third GAA FET 610.

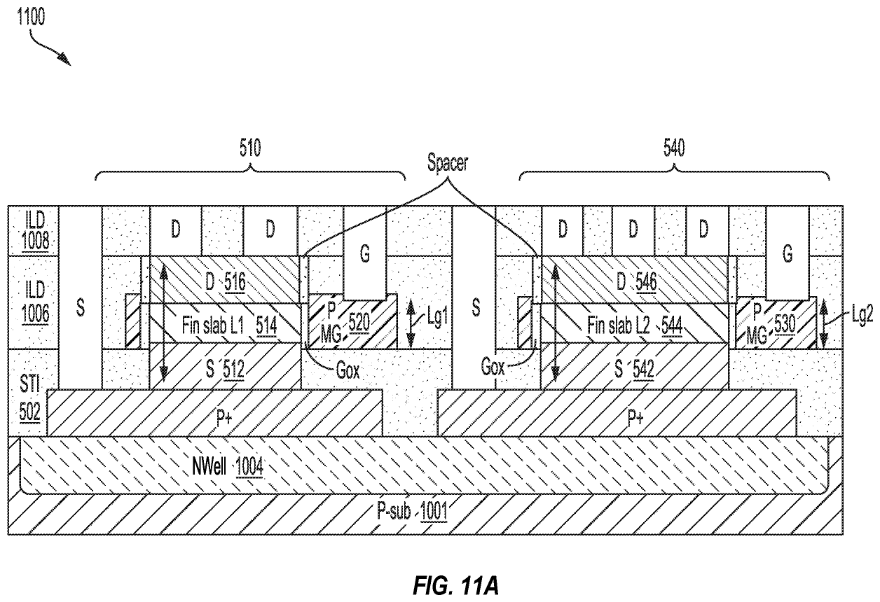

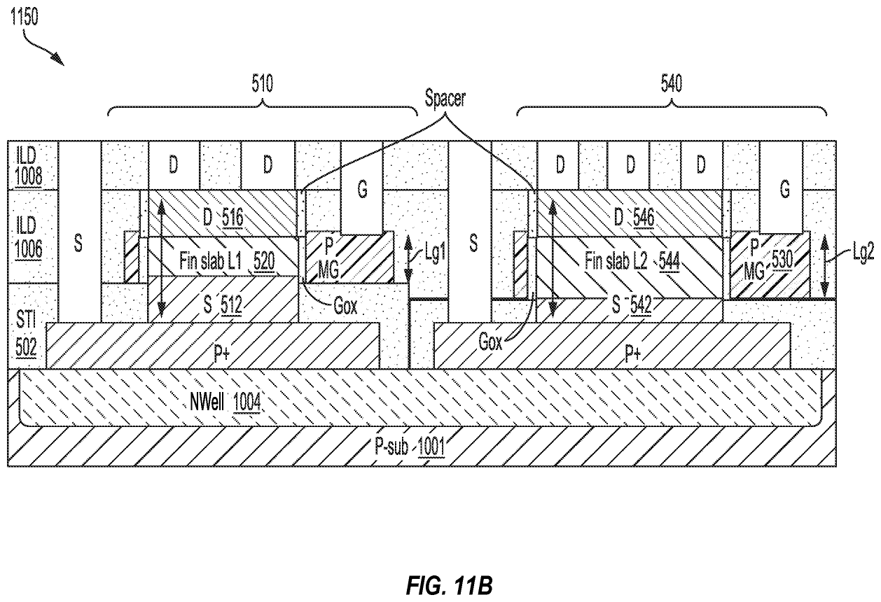

FIGS. 11A and 11B illustrate cross-sectional views of the horizontal GAA FETs shown in FIG. 6, according to aspects of the present disclosure. FIG. 11A shows a cross-sectional view along the X-X″ axis of the first GAA FET 510 and the second GAA FET 540 of the integrated circuit shown in FIG. 6. In this configuration, an integrated circuit 1100 includes a substrate 1001 (e.g., a P-type semiconductor substrate (P-sub)), including an N-type well (N-well 1004) supporting the first GAA FET 510 and the second GAA FET 540 in a PMOS configuration.

The cross-sectional view of FIG. 11A illustrates nano-sheet structures including the drain region 516 stacked on the channel region 514, which is stacked on the source region 512. The gate 520 is shown surrounding a gate oxide Gox on the channel region 514. Spacers are shown on sidewalls of the drain region 516 in the cross-sectional view. Drain contacts (D) to the drain region 516 are also provided. In this configuration, a first fin slab length (L1) of the first nano-sheet structure of the first GAA FET 510 is shown. A gate length (Lg1) of the first GAA FET 510 is shown. The integrated circuit 1100 includes the STI region 502, the first ILD 1006 on the STI region 502, and a second ILD 1008 on the first ILD 1006. These layers may be formed using an oxide film, which may be composed of silicon nitride (SiN).

FIG. 11A also shows the second GAA FET 540 of the integrated circuit shown in FIG. 6. This configuration of the integrated circuit 1100 shows nano-sheet structures including the drain region 546 stacked on the channel region 544, which is stacked on the source region 542 of the second GAA FET 540. The gate 530 is shown surrounding the gate oxide Gox on the channel region 544. Spacers are shown on sidewalls of the drain region 546 in the cross-sectional view. Drain contacts (D) to the drain region 546, a source contact (S) to the source region 542, and a gate contact (G) to the gate 530 are provided. In this configuration, a second fin slab length (L2) of the first nano-sheet structure of the second GAA FET 540 is greater than the first fin slab length L1 of the first GAA FET 510. The gate length (Lg1) of the second GAA FET 540, however, matches the gate length Lg1 of the first GAA FET 510. In this configuration, a first channel width (e.g., the first fin slab length L1) of the channel region 514 of the first nano-sheet structure is less than a second channel width (e.g., the first fin slab length L1) of the channel region 544 of the second nano-sheet structure of the second GAA FET 540.

FIG. 11B shows a cross-sectional view along the X-X″ axis of the first GAA FET 510 and the third GAA FET 610 of the integrated circuit shown in FIG. 6. In this configuration, an integrated circuit 1150 is shown in a similar configuration to the integrated circuit 1100 shown in FIG. 11A. In the configuration shown in FIG. 11B, however, the gate length (Lg2) of the second GAA FET 540 is greater than the gate length Lg1 of the first GAA FET 510. Variation of the gate length as well as the nano-slab length of the integrated circuit 1150 provides improved flexibility for designing the first GAA FET 510 and the second GAA FET 540, by enabling different configurations of channel widths and channel lengths.

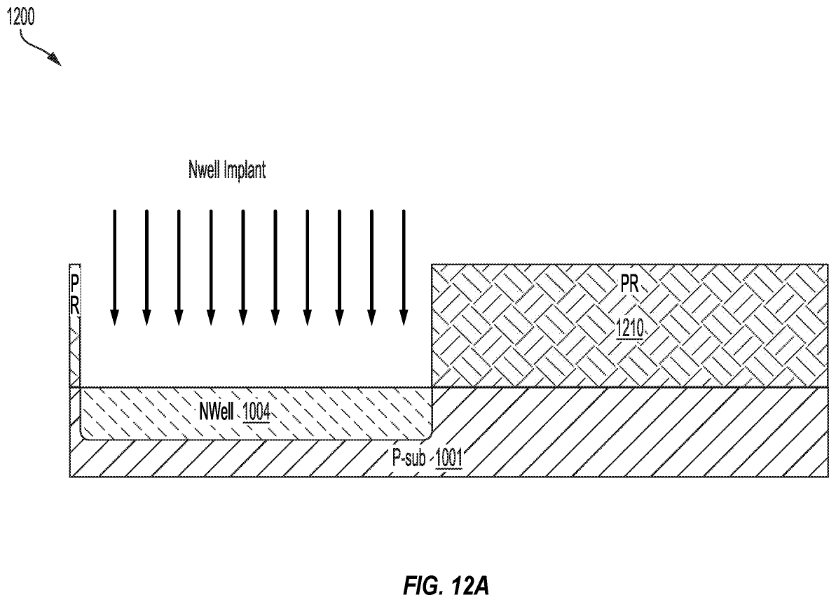

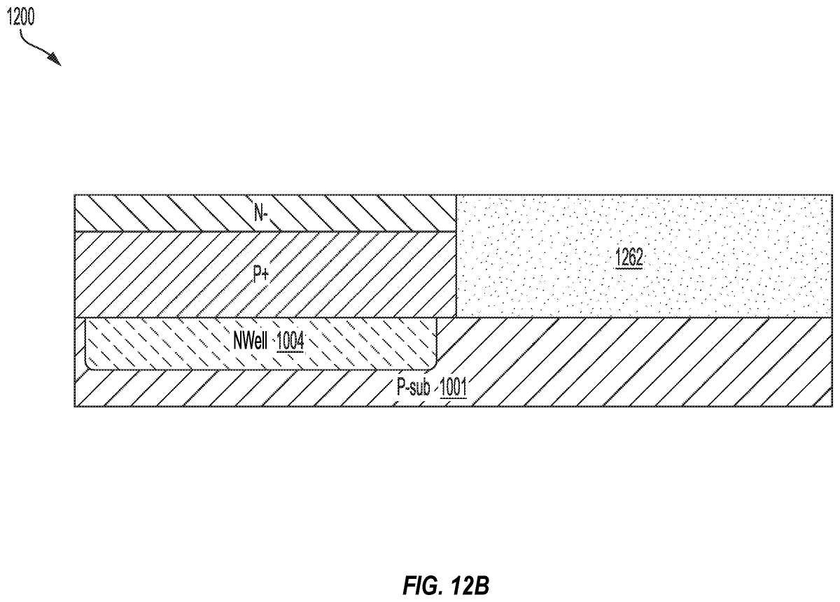

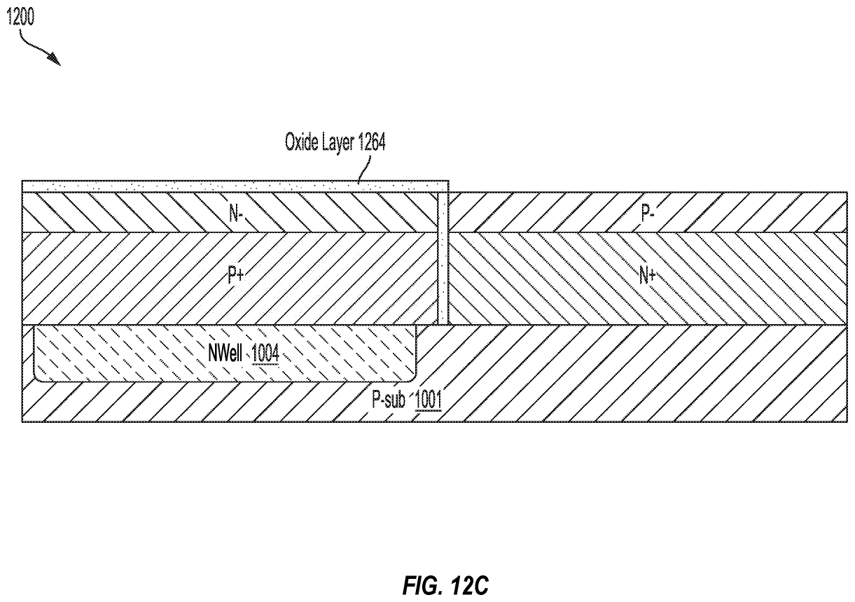

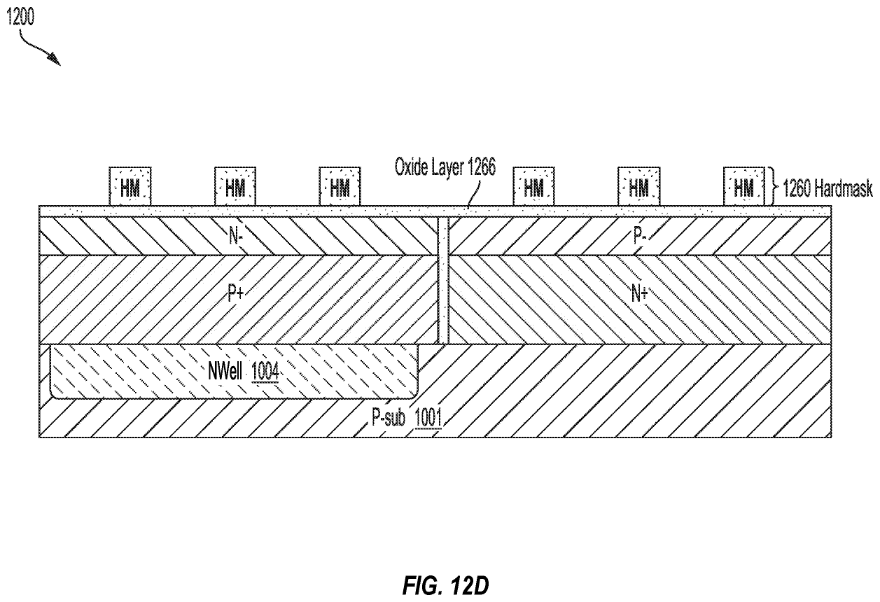

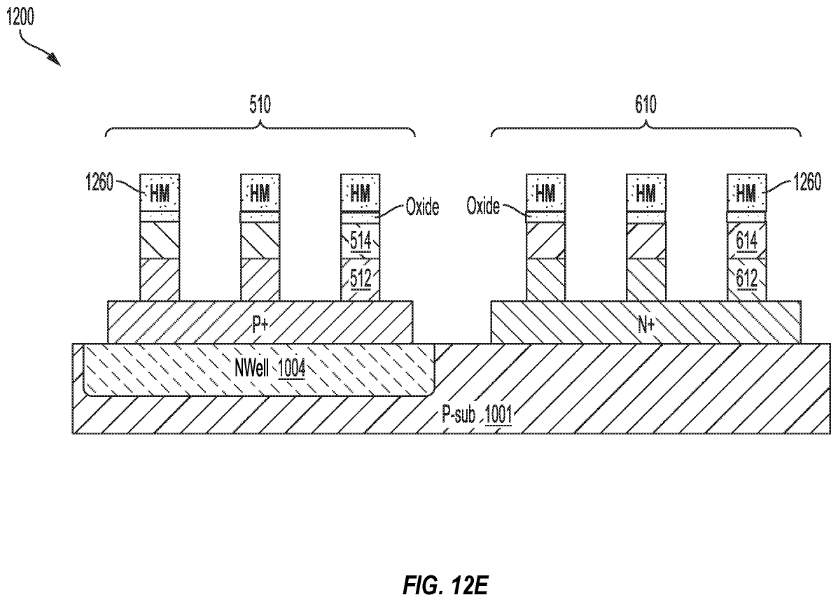

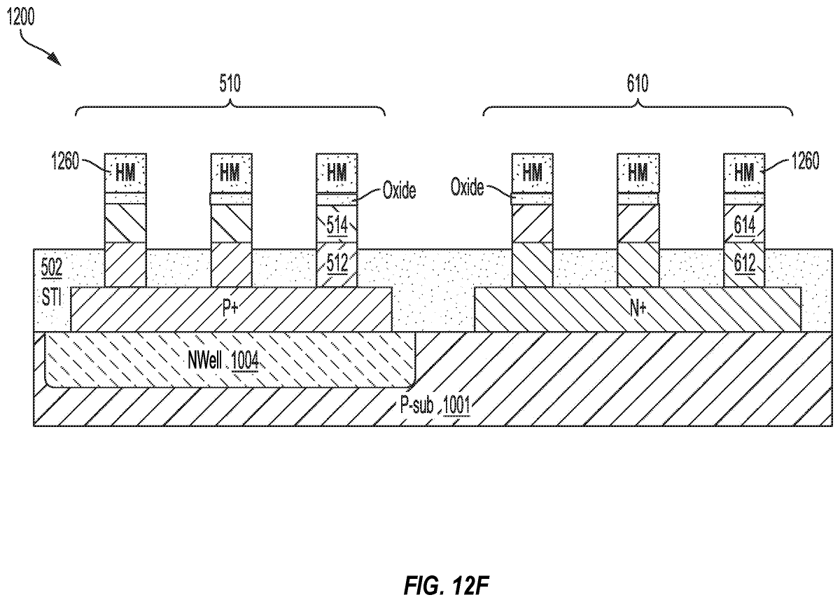

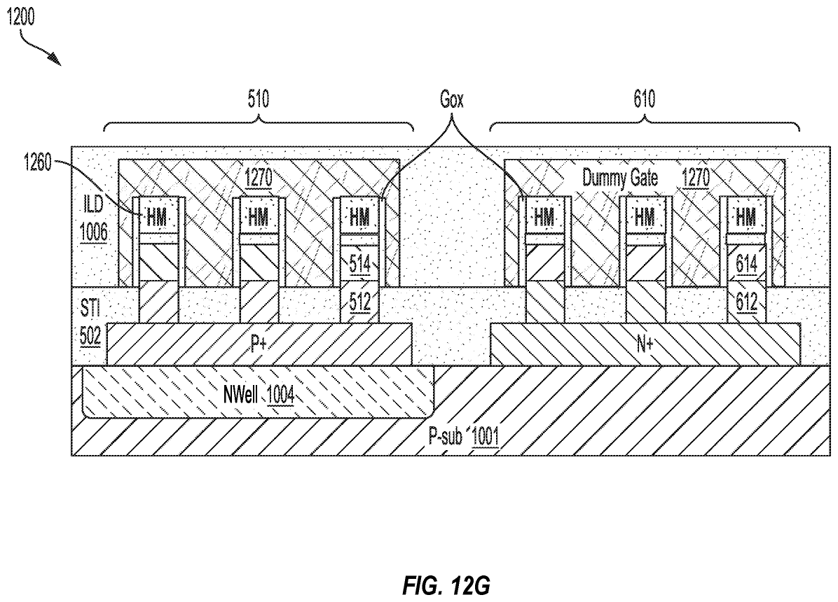

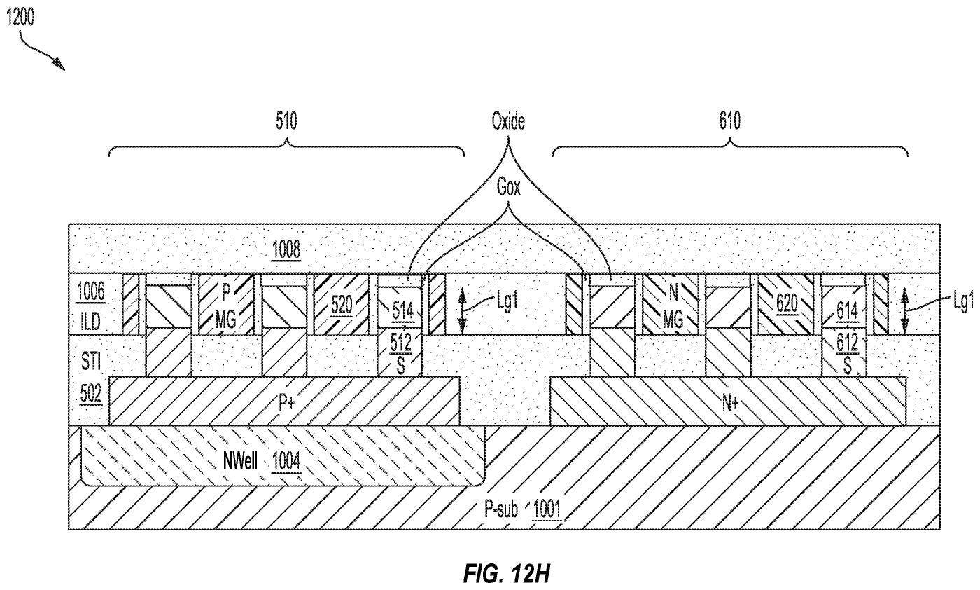

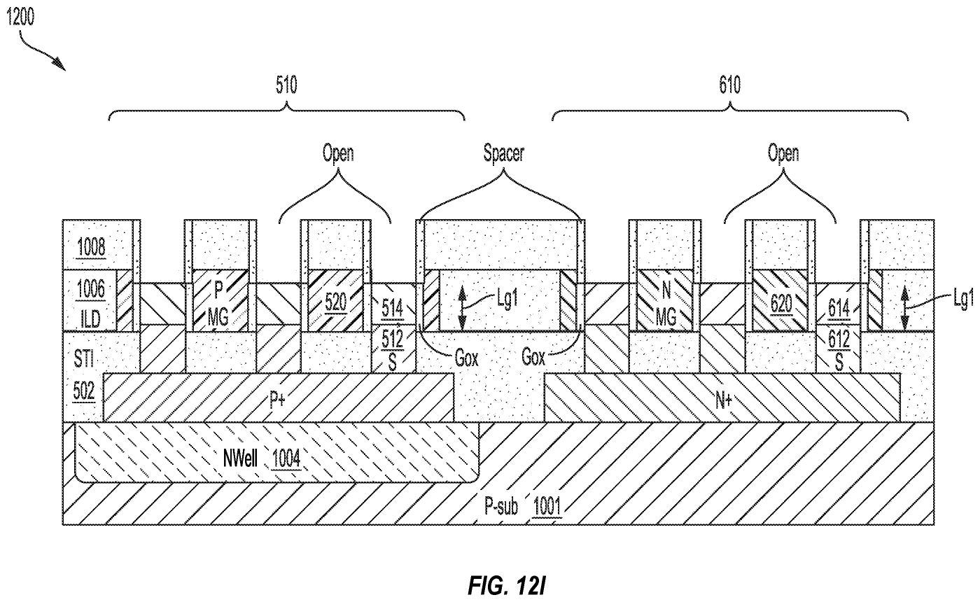

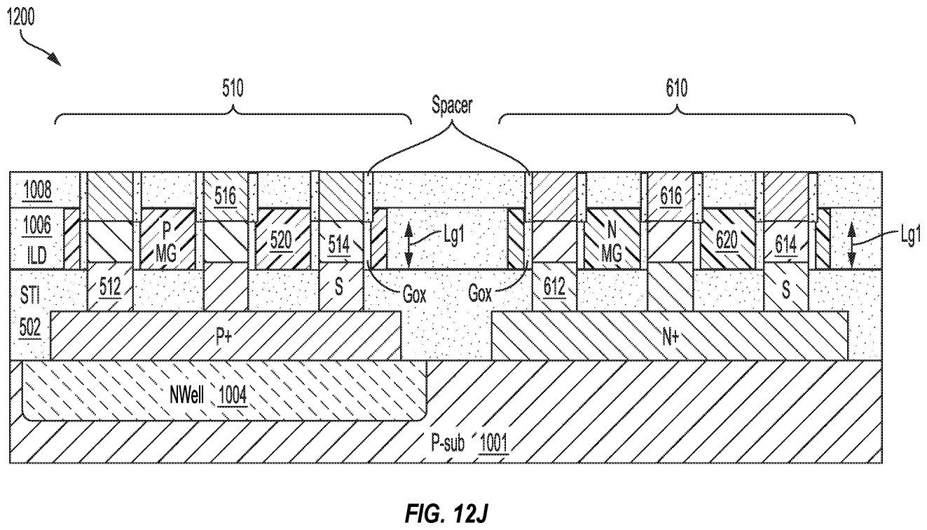

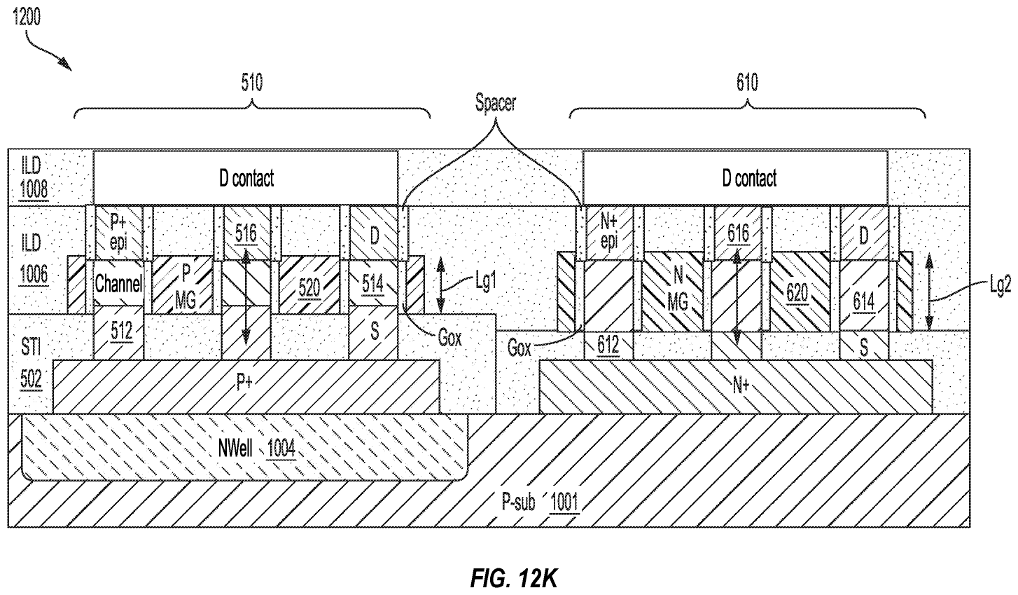

FIGS. 12A-12K are block diagrams 1200 illustrating a process for fabricating the integrated circuit of FIG. 6, including horizontal, gate-all-around (GAA) field effect transistors (FETs), according to aspects of the present disclosure.

FIG. 12A illustrates formation of an N-type well (e.g., the N-well 1004) in a P-type substrate (e.g., the substrate 1001). A process of forming the N-well 1004 may including performing an N-well photoresist process to define the N-well 1004 in the substrate 1001. In this example, the N-well 1004 is defined in the substrate 1001 by depositing a photoresist (PR) pattern 1210. Once the PR pattern 1210 is deposited to define the N-well 1004, an N-well implant is performed on a portion of the substrate 1001 exposed by the PR pattern 1210. The process of forming the N-well 1004 is completed by performing a photoresist ash process. The ash process is followed by stripping and cleaning the substrate 1001 to completely remove the PR pattern 1210 from the substrate 1001.

FIG. 12B illustrates formation of a P-type layer (P+) on the N-well of the substrate to enable formation of a drain region (e.g., drain region 512), and formation of an N-type layer (N−) on the P-type later to enable formation of a channel region (e.g., channel region 514). The formation of a P+ region and an N− region includes depositing an oxide film on the substrate 1001. Next, a photoresist (PR) process/etch process is performed to remove the oxide and open the P+ region. The PR process is followed by a photoresist ash process to define an opening for forming the P+ region. The ash process is followed by stripping and cleaning to form an oxide layer 1262 having an opening for growing the P+ region.

Once the opening for the P+region is defined, an epitaxial process grows a P-type semiconductor film in the opening defined by the oxide layer 1262. The P-type semiconductor film may be a P-type doped (P-doped) semiconductor material, such as silicon (Si), silicon germanium (SiGe), a column III and column V compound, or column II and column VI compound semiconductor material. Once formation of the P-type semiconductor film is complete, the epitaxial process continues by growing an N-type semiconductor film on the P-type semiconductor film. The N-type semiconductor film may be an N-type doped (N-doped) semiconductor material, such as N-doped silicon (Si), silicon germanium (SiGe), a column III and column V, or column II and column VI compound semiconductor material. In this configuration, the P+ layer provides a material to enable formation of the drain region 512 of the nano-sheet structures. In addition, the N− layer provides a region for forming a channel region of the nano-sheet structures of a horizontal GAA FET in a PMOS configuration, according to aspects of the present disclosure.

FIG. 12C illustrates formation of thin-film N-type and P-type layers to enable formation of a horizontal GAA FET in an NMOS configuration, according to aspects of the present disclosure. In this example, an oxide film is deposited on the N− layer and an oxide layer 1264. Next, a photoresist (PR) process/etch process removes the oxide layer 1264 to open an N+ region exposing a portion of the substrate 1001. The PR process is followed by a photoresist ash process to define an opening for forming the N+ region. The ash process is followed by stripping and cleaning to form an oxide layer pattern to define an opening for growing the P+region.

Once the opening for the N+ region is defined, an epitaxial process grows an N-type semiconductor film in the opening defined by the oxide layer 1264. The N-type semiconductor film may be an N-type doped (N-doped) semiconductor material, such as silicon (Si), silicon germanium (SiGe), a column III and column V compound, or a column II and column VI compound semiconductor material. Once formation of the N-type semiconductor film is complete, the epitaxial process continues by growing a P-type semiconductor film on the N-type semiconductor film. The P-type semiconductor film may be a P-type doped (P-doped) semiconductor material, such as N-doped silicon (Si), silicon germanium (SiGe), a column III and column V, or column II and column VI compound semiconductor material. In this configuration, the N+ layer provides a material to enable formation of the drain region 516 of the nano-sheet structures (e.g., nano-slab) described above. In addition, the P+ layer provides a region for forming a channel region of the nano-sheet structures of a horizontal GAA FET in an NMOS configuration, according to aspects of the present disclosure.

FIG. 12D illustrates formation of a hardmask pattern to define nano-structures of a horizontal GAA FET in NMOS and PMOS configurations, according to aspects of the present disclosure. In this example, an oxide layer 1266 is formed on the N− layer and the P− layer, which are separated by a portion of the oxide layer 1266. Next, a hardmask film is deposited on the oxide layer 1266. The hardmask film may be a silicon nitride (SiN) film. This hardmask film is subjected to a photoresist (PR)/etch process to define a nano-slab hardmask pattern 1260. Formation of the nano-slab hardmask pattern 1260 is completed by performing a photoresist ash process on the hardmask film. The ash process is followed by stripping and cleaning to form the nano-slab hardmask pattern 1260 to define the nano-slab structures of a horizontal GAA FET.

FIG. 12E illustrates an etch process to form nano-slab structures of horizontal GAA FETs, according to aspects of the present disclosure. In this example, an etch process is performed according to the nano-slab hardmask pattern 1260 to form nano sheet structures of the first GAA FET 510 and the third GAA FET 610 of FIG. 6. In this example, the N+ region and the P+ region are photo-defined and etched to define the P+ region supporting first nano-slab structures of the first GAA FET 510 and the N+ region supporting the second nano-slab structures of the third GAA FET 610. This process is completed by cleaning the first and second nano-slab structures and the P+ and N+ regions.

FIG. 12F illustrates formation of an STI region of horizontal GAA FETs, according to aspects of the present disclosure. In this example, an oxide layer is deposited on the substrate 1001 as well as the N-well 1004, and the nano-slab structures of the first GAA FET 510 and the third GAA FET 610. Deposition of the oxide layer is followed by a chemical mechanical polish (CMP) process or other like planarization process. Next, the oxide layer is recess etched to expose portions of the source region 512 of the first GAA FET 510 and the source region 612 of the third GAA FET 610 to form the STI region 502.

FIG. 12G illustrates formation of dummy gates on nano-slab structures of horizontal GAA FETs, according to aspects of the present disclosure. In this example, a dummy gate material (e.g., polysilicon) is deposited on the hardmask (HM) 1260, the channel region 514, 614 (e.g., an epitaxial channel region), and the source region 512, 612 of the nano-slab structures of the first GAA FET 510 and the third GAA FET 610. Deposition of the dummy gate material is followed by a photoresist (PR)/etch process to pattern the dummy gate material to form dummy gates 1270. Next, a first interlayer dielectric (ILD) 1006 is deposited on the dummy gates 1270 and the STI region 502. Deposition of the first ILD 1006 is followed by a planarization process (e.g., a CMP process) to planarize an exposed surface of the first ILD 1006. This process also includes formation of an oxide that is retained on the channel regions 514, 614 to form a gate oxide (Gox).

FIG. 12H illustrates replacement of dummy gates 1270 on nano-slab structures to form gates horizontally surrounding channel regions of the nano-slab structures, according to aspects of the present disclosure. In this example, the dummy gates 1270 on the nano-slab structures of the first GAA FET 510 and the third GAA FET 610 are separately opened. Once opened, the dummy gate material of the dummy gates 1270 is removed. Once removed, the gates 520, 620 are formed on the STI region 502 and surrounding the channel region (e.g., 514, 614) on four sides. Formation of the gates 520, 620 may be performed using a high-K metal gate process. Formation of the gates 520, 620 is followed by a planarization process on the first ILD 1006, the gates 520, 620, and an oxide on the channel regions 514, 614. Next, a second ILD 1008 is deposited on the first ILD 1006, the gates 520, 620, and an oxide on the channel regions 514, 614.

FIG. 121 illustrates opening (e.g., a drain opening) of nano-slab structures in preparation for the drain region 516 of the first GAA FET 510 and the drain region 616 of the third GAA FET 610, as shown in FIG. 12J, according to aspects of the present disclosure. In this example, the second ILD 1008 is subjected to a photoresist (PR)/etch process to separately open the nano-slab structures of the first GAA FET 510 and the third GAA FET 610 and expose the channel region 514 and the channel region 614. Once opened, spacers are formed on sidewalls of the openings in the nano-slab structures by depositing and etching (e.g., isotopically etching) a silicon nitride (SiN) film. This process of forming spacers is completed by cleaning the openings in the nano-slab structures.

FIG. 12J illustrates formation of the drain region 516 of the first GAA FET 510 and the drain region 616 of the third GAA FET 610, according to aspects of the present disclosure. In this example, an N+ strain film is epitaxially grown in the openings of the nano-slab structure of the first GAA FET 510, corresponding to an NMOS configuration of the first GAA FET 510. In addition, a P+ strain film is epitaxially grown in the openings of the nano-slab structure of the third GAA FET 610, corresponding to a PMOS configuration of the third GAA FET 610. This strained drain formation process is completed by planarizing (e.g., CMP) and cleaning the drain regions 516, 616 and the second ILD 1008.

FIG. 12K illustrates drain contact formation to the drain region 516 of the first GAA FET 510 and the drain region 616 of the third GAA FET 610, according to aspects of the present disclosure. Formation of the drain contacts (D contact) begins with depositing an ILD film (e.g., the second ILD 1008). Once deposited, the ILD film is subjected to a photoresist (PR)/etch process to form openings (e.g., a contact opening) for the drain contacts. Once opened, a barrier conductive material and a contact conductive material (e.g. tungsten (W)) are deposited in the opening defined in the ILD film. The drain contact formation process is completed by performing a planarization process (e.g., CMP) on the drain contacts and the second ILD 1008. This drain contact process may further include middle-of-line (MOL) and back-end-of-line (BEOL) metallization processes for contacting the drain contacts.

Although the first GAA FET 510 and the third GAA FET 610 are shown, it is understood that this is exemplary only, and the process described above may also apply to more or fewer GAA FETs.

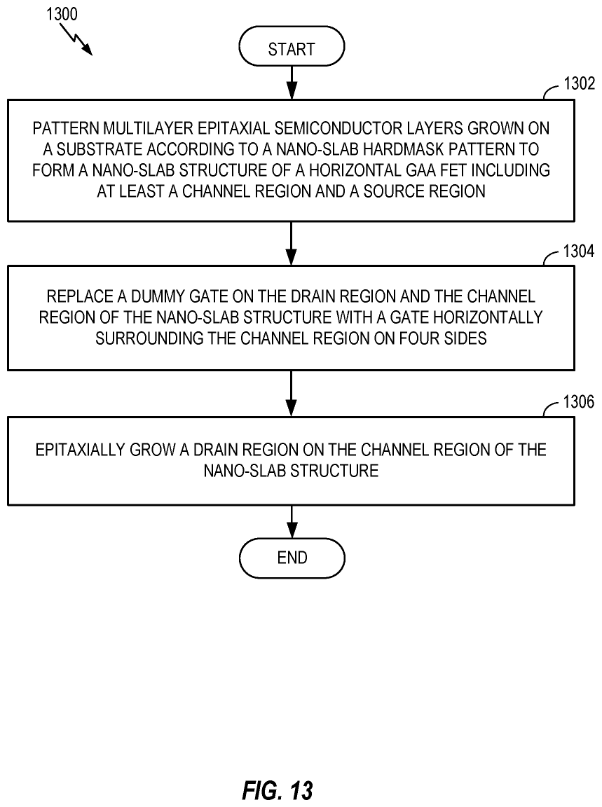

FIG. 13 is a process flow diagram illustrating a method of fabricating a horizontal gate-all-around (GAA) field effect transistor (FET), according to aspects of the present disclosure. The method 1300 may begin at block 1302 with patterning of multilayer epitaxial semiconductor layers grown on a substrate according to a nano-slab hardmask pattern to form a nano-slab structure including a channel region between a source region and a drain region. For example, in FIGS. 12D and 12E, an etch process is performed according to the nano-slab hardmask pattern 1260 to form nano sheet structures of the first GAA FET 510 and the third GAA FET 610 of FIG. 6.

At block 1304, a dummy gate on the drain region and the channel region of the nano-slab structure is replaced with a gate horizontally surrounding the channel region on four sides. For example, FIGS. 12G and 12H illustrate replacement of dummy gates 1270 on nano-slab structures to form gates horizontally surrounding channel regions of the nano-slab structures. In this example, a gate 520 of the first GAA FET 510 is formed on the STI region 502, surrounding the channel region 514 on four sides. In addition, a gate 620 of the third GAA FET 610 is formed on the STI region 502, surrounding the channel region 614 on four sides. In this example, the gate 520 and the gate 620 are shown as high-K metal gates (HKMGs).

At block 1306, a drain region is epitaxially grown on the channel region of the nano-slab structure. For example, FIGS. 12I and 12J illustrate opening of nano-slab structures in preparation for the drain region 516 of the first GAA FET 510 and the drain region 616 of the third GAA FET 610. In this example, an N+ strain film is epitaxially grown in the openings of the nano-slab structure of the first GAA FET 510, corresponding to an NMOS configuration of the first GAA FET 510. In addition, a P+ strain film is epitaxially grown in the openings of the nano-slab structure of the third GAA FET 610, corresponding to a PMOS configuration of the third GAA FET 610.

According to aspects of the present disclosure, a horizontal, gate-all-around (GAA) field effect transistor (FET) compatible with complementary metal oxide semiconductor (CMOS) integration is described. The horizontal GAA FET includes a shallow trench isolation (STI) region on a substrate. The horizontal GAA FET also includes a nano-sheet structure (e.g., a nano-slab) on the substrate and extending through the STI region. The nano-sheet structure may include a drain/source region stacked on a source/drain region. In one configuration, the nano-sheet structure may also include a channel region between the drain/source region and the source/drain region. In this configuration, the horizontal GAA FET includes a gate on the STI region and horizontally surrounding the channel region on four sides of the channel region of the nano-sheet structure. In aspects of the present disclosure, a gate length of the horizontal GAA FET is defined by an epitaxial thickness of the channel region of the nanostructure. In addition, a width of a channel region may be varied by adjusting a nano-slab length of the nano-sheet structures.

According to an aspect of the present disclosure, horizontal gate-all-around (GAA) field effect transistor (FET) is described. In one configuration, the horizontal GAA FET includes means for horizontally surrounding a first channel region on four sides, the means for horizontally surrounding on a shallow trench isolation (STI) region. The means for horizontally surrounding may be the first GAA FET 510 of FIG. 5. In another aspect, the aforementioned means may be any module or any apparatus or material configured to perform the functions recited by the aforementioned means.

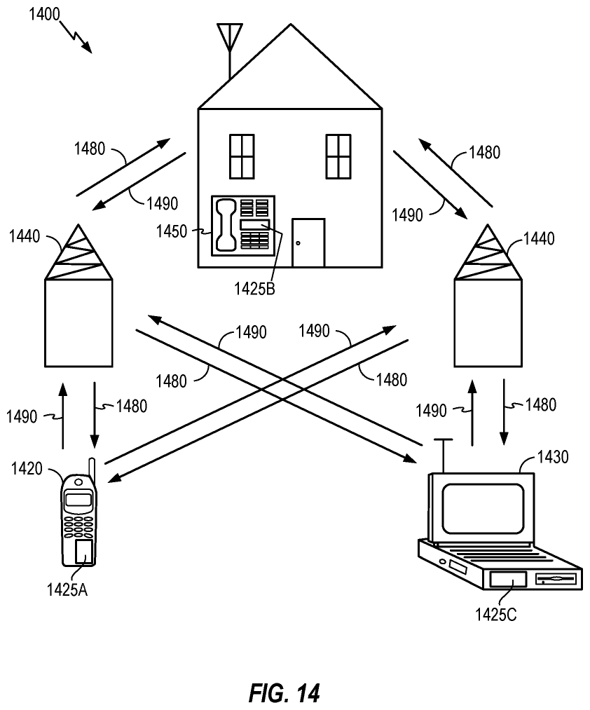

FIG. 14 is a block diagram showing an exemplary wireless communication system 1400 in which an aspect of the disclosure may be advantageously employed. For purposes of illustration, FIG. 14 shows three remote units 1420, 1430, and 1450, and two base stations 1440. It will be recognized that wireless communication systems may have many more remote units and base stations. Remote units 1420, 1430, and 1450 include IC devices 1425A, 1425C, and 1425B that include the disclosed GAA FETs. It will be recognized that other devices may also include the disclosed GAA FETs, such as the base stations, switching devices, and network equipment. FIG. 14 shows forward link signals 1480 from the base station 1440 to the remote units 1420, 1430, and 1450, and reverse link signals 1490 from the remote units 1420, 1430, and 1450 to base station 1440.

In FIG. 14, remote unit 1420 is shown as a mobile telephone, remote unit 1430 is shown as a portable computer, and remote unit 1450 is shown as a fixed location remote unit in a wireless local loop system. For example, the remote units may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 14 illustrates remote units according to the aspects of the disclosure, the disclosure is not limited to these exemplary illustrated units. Aspects of the disclosure may be suitably employed in many devices, which include the disclosed GAA FETs.

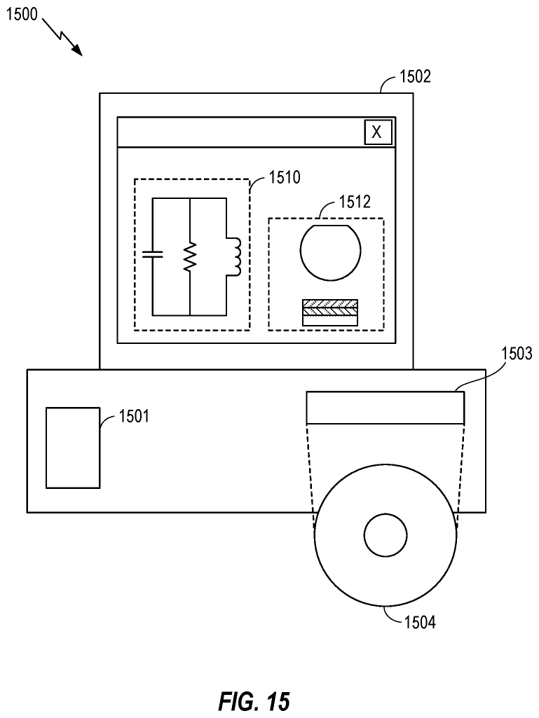

FIG. 15 is a block diagram illustrating a design workstation used for circuit, layout, and logic design of an IC structure, such as the GAA FET disclosed above. A design workstation 1500 includes a hard disk 1501 containing operating system software, support files, and design software such as Cadence or OrCAD. The design workstation 1500 also includes a display 1502 to facilitate design of a circuit 1510 or a nano-slab structure 1512 including a GAA FET. A storage medium 1504 is provided for tangibly storing the design of the circuit 1510 or the nano-slab structure 1512. The design of the circuit 1510 or the nano-slab structure 1512 may be stored on the storage medium 1504 in a file format such as GDSII or GERBER. The storage medium 1504 may be a CD-ROM, DVD, hard disk, flash memory, or other appropriate device. Furthermore, the design workstation 1500 includes a drive apparatus 1503 for accepting input from or writing output to the storage medium 1504.

Data recorded on the storage medium 1504 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1504 facilitates the design of the circuit 1510 or the nano-slab structure 1512 by decreasing the number of processes for designing semiconductor wafers.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A horizontal gate-all-around (GAA) field effect transistor (FET), comprising:
a substrate;
a shallow trench isolation (STI) region on the substrate;
a first nano-sheet structure on the substrate and extending through the STI region, the first nano-sheet structure comprising a first drain/source region stacked on a first source/drain region, and a first channel region between the first drain/source region and the first source/drain region; and
a first gate on the STI region and horizontally surrounding the first channel region on four sides.

2. The horizontal GAA FET of claim 1, in which the first nano-sheet structure comprises a vertical nano-slab on the substrate, the vertical nano-slab vertically extending through and from the STI region.

3. The horizontal GAA FET of claim 1, in which the first channel region comprises an epitaxial channel region.

4. The horizontal GAA FET of claim 3, in which a gate length of the first gate is defined by a thickness of the epitaxial channel region.

5. The horizontal GAA FET of claim 1, in which the first gate comprises a high-K metal gate.

6. The horizontal GAA FET of claim 1, in which the first drain/source region is an epitaxial drain/source stress region.

7. The horizontal GAA FET of claim 1, further comprising:
a second nano-sheet structure on the substrate and extending through the STI region, the second nano-sheet structure comprising a second drain/source region stacked on a second source/drain region, and a second channel region between the second drain/source region and the second source/drain region; and
a second gate on the STI region and horizontally surrounding the second channel region.

8. The horizontal GAA FET of claim 7, in which a first gate length of the first gate is different from a second gate length of the second gate.

9. The horizontal GAA FET of claim 7, in which a first nano-slab length of the first nano-sheet structure is different from a second nano-slab length of the second nano-sheet structure.

10. The horizontal GAA FET of claim 7, in which a first nano-slab length of the first nano-sheet structure is less than a second nano-slab length of the second nano-sheet structure, such that a first channel width of the first channel region of the first nano-sheet structure is less than a second channel width of the second channel region of the second nano-sheet structure.

11. A method for fabricating a horizontal gate-all-around (GAA) field effect transistor (FET), the method comprising:
patterning multilayer epitaxial semiconductor layers grown on a substrate according to a nano-slab hardmask pattern to form a nano-slab structure of the horizontal GAA FET, including at least a channel region and a source region;
replacing a dummy gate on the channel region of the nano-slab structure with a gate on a shallow trench isolation (STI) region, the gate horizontally surrounding the channel region on four sides; and
epitaxially growing a drain region on the channel region of the nano-slab structure.

12. The method of claim 11, in which the patterning of the multilayer epitaxial semiconductor layers further comprises:
depositing an oxide layer on the substrate and the nano-slab structure;
planarizing the oxide layer; and
recess etching the oxide layer to expose portions of the drain region of the nano-slab structure.

13. The method of claim 11, further comprising forming the dummy gate on a hardmask stacked on the channel region of the nano-slab structure.

14. The method of claim 13, in which forming the dummy gate comprises:
depositing a dummy gate material on the hardmask (HM), the channel region, and the source region of the nano-slab structure;
patterning and etching the dummy gate material to form the dummy gate;
depositing an interlayer dielectric (ILD) on the dummy gate and the STI region; and
planarizing an exposed surface of the ILD.

15. The method of claim 11, in which replacing the dummy gate comprises:
opening the dummy gate on the nano-slab structure;
removing dummy gate material of the dummy gate;
forming the gate on the STI region and surrounding the channel region;
planarizing a first interlayer dielectric (ILD) on the STI region and the gate; and
depositing a second ILD on the first ILD and the gate.

16. The method of claim 15, in which epitaxially growing the drain region further comprises:
patterning and etching the second ILD to open the nano-slab structure and expose the channel region;
forming spacers on sidewalls of a drain opening in the nano-slab structure; and
cleaning the drain opening in the nano-slab structure.

17. The method of claim 16, in which epitaxially growing the drain region further comprises:
epitaxially growing a strain film in the drain opening of the nano-slab structure; and
planarizing and cleaning the strain film and the second ILD.

18. The method of claim 17, further comprising:
depositing an ILD film on the second ILD and the strain film;
patterning and etching the ILD film to form a contact opening for a drain contact;
depositing a barrier conductive material and a contact conductive material in the contact opening defined in the ILD film to form the drain contact; and
planarizing the drain contact and the ILD film as the second ILD.

19. A horizontal gate-all-around (GAA) field effect transistor (FET), comprising:
a substrate;
a shallow trench isolation (STI) region on the substrate;
a first nano-sheet structure on the substrate and extending through the STI region, the first nano-sheet structure comprising a first drain/source region stacked on a first source/drain region, and a first channel region between the first drain/source region and the first source/drain region; and
means for horizontally surrounding the first channel region on four sides, the means for horizontally surrounding on the STI region.

20. The horizontal GAA FET of claim 19, in which the first nano-sheet structure comprises a vertical nano-slab on the substrate, the vertical nano-slab vertically extending through and from the STI region.
